(19) United States
(12) Patent Application Publication
(10) Pub. No.: US 2017/0338453 A1
(43) Pub. Date: Nov. 23, 2017

(54) ORIGAMI ENABLED DEFORMABLE ELECTRONICS

(71) Applicant: ARIZONA BOARD OF REGENTS ON BEHALF OF ARIZONA STATE UNIVERSITY, Scottsdale, AZ (US)

(72) Inventors: Hongyu Yu, Chandler, AZ (US); Hanqing Jiang, Chandler, AZ (US); Rui Tang, Mesa, AZ (US); Mengbing Liang, Mesa, AZ (US); Ruirui Han, Tempe, AZ (US); Zeming Song, Tempe, AZ (US)

(21) Appl. No.: 15/523,298

(22) PCT Filed: Nov. 4, 2015
(86) PCT No.: PCT/US2015/059006

§ 371 Date: Apr. 28, 2017

Related U.S. Application Data
(60) Provisional application No. 62/074,830, filed on Nov. 4, 2014.

(51) Int. Cl. H01M 2/10; H01M 2/20; H01M 10/0585; H01M 10/0525; H02S 30/20; H01L 23/538

(52) U.S. Cl. CPC H01M 2/1061; H01M 10/0585; H01M 10/0525; H01M 2/204; H01L 23/5387; H02S 30/20

(57) ABSTRACT

The invention is directed to an electronic device comprising a first functional body, a second functional body, and at least one serpentine interconnect connecting the first functional body to the second functional body, wherein the serpentine interconnect is suspended in air to allow for stretching, flexing or compression.

### CROSS-REFERENCE TO RELATED APPLICATION

This application claims priority to U.S. Provisional Patent Application No. 62/074,830, filed Nov. 4, 2014, the entire disclosure of which is hereby incorporated by reference

### FIELD OF THE INVENTION

This application relates to origami enabled manufacturing systems and methods and, more particularly, to systems and methods for manufacturing functional materials, structures, devices and/or systems having an adjustable size, shape and/or local structures, based on origami principles.

### BACKGROUND

Origami can be used to transform a flat sheet of paper or flexible board into a finished sculpture through folding and sculpting techniques. Such finished sculptures can be very intricate with detailed and complex shapes. Traditional origami has been used primarily in artistic applications, but its use in other more industrial areas is being investigated.

For example, in small or micro-scale manufacturing processes (e.g., from centimeters to micrometers to nanometers), orgami has been explored to form flexible, compact devices. Indeed, flexible, foldable and/or stretchable electronics are emerging as an attractive and promising new industry. Such electronics can be incorporated into wearable devices, such as flexible displays, stretchable circuits, hemispherical electronic eyes, and epidermal devices. However, such devices are limited by manufacturing technology which is not scalable, has a low yield, and is expensive and fragile. Only very simple folding and sculpting methods have been explored to fabricate such structures due to their small size. Moreover, the current material choice is limited, thereby limiting the functionality of such electronics.

Accordingly, there is a need in the pertinent art for a universal technology to fully employ origami structures with the integration of soft and hard materials to produce wide functionality, reduce the space required, and improve portability and performance. The products can be from nano-, micro-, centi- to meter level in scale.

### SUMMARY

Described herein are origami enabled manufacturing systems and methods. In one aspect, the origami enabled manufacturing system can use conventional manufacturing technology to produce fully functional material, structures, devices and/or systems on a substantially planar substrate. In use, the planar substrate can then be converted into a three-dimensional structure with origami shape by self-assembling and/or from external forces. The resulting origami 3-D products can provide smaller projection area (i.e., a more compact product or dense product), higher portability, and deformability from folds for fully transformable devices and/or better performance in certain applications. Furthermore, the capability of repeatedly folding and unfolding of origami products provides a great platform of foldable, flexible, stretchable and/or curvilinear electronics, such as stretchable/flexible solar cells, stretchable/flexible antenna and the like.

The origami enabled manufacturing system can include a plurality of functional bodies, and each functional body can have a plurality of side edges. The plurality of functional bodies can be arrayed in a predetermined pattern. The plurality of side edges can define a plurality of creases in the predetermined pattern and at least one side edge of each functional body can be positioned in opposition to at least one side edge of another functional body in the predetermined pattern.

The origami enabled manufacturing system can include a plurality of connection members, and at least one connection member can be coupled to and positioned between opposed functional bodies. In an aspect, each connection member can be in a fixed position, in which no relative movement between connected functional bodies can be allowed. In another aspect, each connection member can be movable and pliable to allow for relative movement between connected functional bodies.

In one aspect, each functional body can include a substrate. In another aspect, each functional body can include a substrate and at least one device attached thereto or formed integrally with the substrate. The substrate can be, for example, a rigid substrate. As another example, the substrate can be a foldable and/or flexible substrate. In still another aspect, the substrate can be, for example, a material, structure, device and the like manufactured as a substantially planar shape using conventional industrial technology. In still another aspect, the functional bodies can be shaped and sized to correspond to a desired origami shape, with the side edges of the functional bodies corresponding to creases in the origami pattern.

The origami enabled manufacturing system can be designed and formed as an array of functional bodies with at least one connection member positioned between and coupled to the functional bodies, according to one aspect. In another aspect, the connection members can be flexible and/or stretchable connection members. For example, the connection members can be electrodes, fluidic channels, mechanical hinges and the like.

In an aspect, the interconnection between the functional bodies includes serpentine shaped conductors. The serpentine shape allows the electronic device to be fully deformable, including but not limited to flexibile, stretchable, twistable, compressible, and foldable. Methods for making functional bodies with serpentine interconnects are also provided.

Additional advantages of the invention will be set forth in part in the description which follows, and in part will be obvious from the description, or may be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### DESCRIPTION OF THE DRAWINGS

These and other features of the preferred embodiments of the invention will become more apparent in the detailed description in which reference is made to the appended drawings wherein:

FIG. 1 is a plan view of an origami enabled manufacturing system according to one aspect of the invention;

FIG. 2 is a photograph of an origami enabled manufacturing system according to one aspect of the invention;

FIG. 3 is a top view of the origami enabled manufacturing system of FIG. 1, showing a connection member;

FIGS. 4A-B are top views of the origami enabled manufacturing system of FIG. 2, showing a connection member undergoing deformation;

FIG. 4C is a graph illustrating the resultant changes in resistance of the connection member of FIGS. 4A-B after deformation;

FIG. 5 is a plurality of views showing a method for forming an origami enabled manufacturing system according to one aspect of the invention;

FIG. 6 is a diagram illustrating the steps of a method for forming a connection member according to one aspect of the invention;

FIG. 7 is a diagram illustrating the steps for coupling the connection member of FIG. 6 to a functional device according to one aspect of the invention;

FIG. 8 is a diagram illustrating the steps of an exemplary method for forming origami enabled stretchable silicon solar cells according to one aspect of the invention;

FIGS. 9A-B are optical photographs of fabricated origami enabled silicon solar cells, whereby FIG. 9A illustrates an unfolded state and FIG. 9B illustrates a folded state according to one aspect of the invention;

FIG. 10 is a diagram illustrating an example fabrication process of an exemplary solar cell according to one aspect of the invention;

FIGS. 11A-H illustrate top and side views of exemplary serpentine interconnect designs according to one aspect of the invention;

FIG. 12 illustrates a method for making islands with serpentine interconnects according to one aspect of the invention;

FIG. 13(A) is a diagram illustrating a process for making serpentine interconnects according to one aspect of the invention;

FIG. 13(B) is a photograph of a serpentine interconnect formed by the process of FIG. 13(A) according to one aspect of the invention;

FIG. 14(A) shows a fabrication process for making serpentine interconnects by according to one aspect of the invention;

FIG. 14(B) is a photograph of a serpentine interconnect formed by the process of FIG. 14(A) according to one aspect of the invention;

FIG. 15 is a diagram illustrating a process of fabricating folded interconnection lines starting from a pre-folded interconnection according to one aspect of the invention;

FIG. 16 is a diagram of a soft encapsulation package in combination with interconnection folding in accordance with one aspect of the invention;

FIG. 17 is a diagram illustrating fabrication of folded interconnection lines starting from a planar interconnection in accordance with one aspect of the invention;

FIG. 18 is a block diagram illustrating a method of designing origami enabled deformable electronics according to one aspect of the invention;

FIG. 19 illustrates top views of sample interconnection structures according to one aspect of the invention;

FIG. 20 are photographs of Sample 1 illustrated in FIG. 19 in various stretched states;

FIG. 21 are photographs of Sample 2 illustrated in FIG. 19 in various stretched states; and

FIG. 22 are photographs of Sample 3 illustrated in FIG. 19 in various stretched states.

### DETAILED DESCRIPTION

The present invention can be understood more readily by reference to the following detailed description, examples, drawings, and claims, and their previous and following description. However, before the present devices, systems, and/or methods are disclosed and described, it is to be understood that this invention is not limited to the specific origami patterns, devices, systems, and/or methods disclosed unless otherwise specified, and, as such, can, of course, vary. It is also to be understood that the terminology used herein is for the purpose of describing particular aspects only and is not intended to be limiting.

The following description of the invention is provided as an enabling teaching of the invention in its best, currently known embodiment. To this end, those skilled in the relevant art will recognize and appreciate that many changes can be made to the various aspects of the invention described herein, while still obtaining the beneficial results of the present invention. It will also be apparent that some of the desired benefits of the present invention can be obtained by selecting some of the features of the present invention without utilizing other features. Accordingly, those who work in the art will recognize that many modifications and adaptations to the present invention are possible and can even be desirable in certain circumstances and are a part of the present invention. Thus, the following description is provided as illustrative of the principles of the present invention and not in limitation thereof.

As used throughout, the singular forms “a,” “an,” and “the” include plural referents unless the context clearly dictates otherwise. Thus, for example, reference to “a crease” can include two or more such creases unless the context indicates otherwise.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

As used herein, the terms “optional” or “optionally” mean that the subsequently described event or circumstance may or may not occur, and that the description includes instances where said event or circumstance occurs and instances where it does not.

The word “or” as used herein means any one member of a particular list and also includes any combination of members of that list.

As used herein, the term “origami” refers to the art of folding in which a flat sheet is transformed into a three-dimensional shape through folding and sculpting techniques. It can, however, also refer to kirigami (in which the sheet is cut in addition to folded), or any other types of “gami”, including wet-folding, modular origami and the like.

Although reference will be made herein to small or micro scale (from cm to micro to nano levels), it is understood that origami enabled manufacturing systems and methods can also be extended to a large scale. For example, in building construction, tiles can be pre-patterned in a factory using the origami principle disclosed herein and then assembled on site.

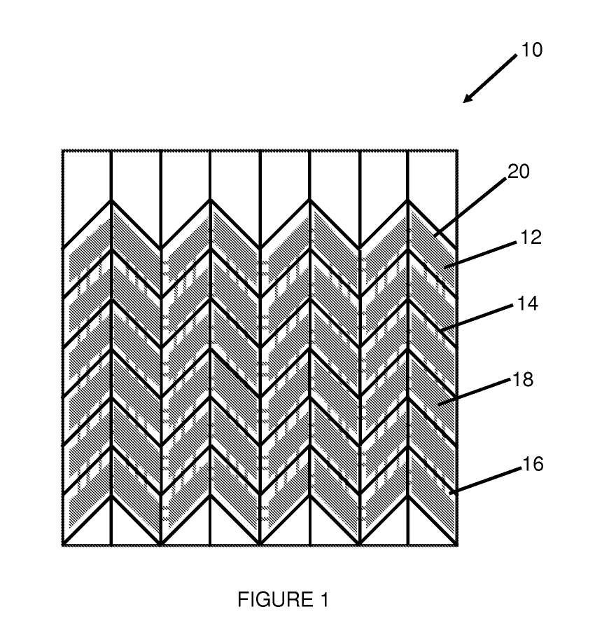

With reference to FIG. 1, the origami enabled manufacturing system 10 of the invention generally includes a plurality of functional bodies 12 coupled together by a plurality of connection members 14 positioned between opposed functional bodies 12. In one aspect, each functional body 12 can include a substrate 16. For example, the substrate 16 can be a silicon substrate. In still another aspect, each functional body 12 can include a substrate 16 and at least one device 18 attached thereto or formed integrally with the substrate 16. The substrate 16 can be, for example, a foldable and/or flexible substrate. Alternatively, the substrate 16 can be a substantially rigid substrate. In still another aspect, the substrate 16 can be, for example, a material, structure, device and the like manufactured as a substantially planar shape using conventional industrial standard technology. In still another aspect, the functional bodies 12 can be shaped and sized to correspond to a predetermined pattern or array (e.g., a desired origami shape), with at least a portion of the side edges 20 of a functional body 12 corresponding to creases in the origami pattern. In another aspect, at least one side edge 20 of each functional body 12 can be positioned in opposition to at least one side edge 20 of another functional body 12 in the predetermined pattern. For example, at least one side edge 20 of each functional body 12 can be positioned adjacent to at least one side edge 20 of another functional body 12 in the predetermined pattern. As another example, at least one side edge 20 of each functional body 12 can be positioned substantially parallel to at least one side edge 20 of another functional body 12 in the predetermined pattern. Thus, the functional bodies 12 can be formed into shapes corresponding to portions of an origami pattern.

The at least one device 18 can be any material, structure, device and/or system. For example, the at least one device could be an electronic device, a pneumatic device, a hydraulic device and the like. In another example, the at least one device 18 can be a metallic material, polymeric material, a wooden material, a textile and the like. As can be appreciated, the at least one device 18 can be almost any material, structure, device and/or system capable of being attached to a substrate.

In one aspect, the at least one connection member 14 can be coupled to and positioned between opposed functional bodies 12. In an aspect, each connection member 14 can be selectively movable between a fixed position, in which no relative movement between connected functional bodies 12 can be allowed, and a pliable position, in which relative movement between connected functional bodies 12 can be allowed.

In one aspect, the origami enabled manufacturing system 10 can include a mechanism for selectively actuating the at least one connection member 14 to allow for the selective displacement of the at least one functional body 12 relative to another functional body 12. For example, the mechanism for selectively actuating the at least one connection member can include an electrode, a fluidic channel, a mechanical hinge and the like (not shown).

In a further aspect, the at least one connection member 14 can be a flexible, pliable and/or stretchable connection member. For example, the at least one connection member 14 can include an electrode, a fluidic channel, a mechanical hinge and the like. However, it is contemplated that, optionally, the at least one connection member 14 does not necessarily have to have a function other than the ability to couple two functional bodies 12 together. That is, for example and without limitation, the at least one connection member 14 can simply be a flexible material such as a flexible polymer. If the at least one connection member 14 includes a plurality of connection members, it is contemplated that each connection member can be a different or the same type of connection member. For example, a first connection member 14 could be an electrode and a second connection member 14 could be a fluidic channel, an electrode, or any other type of connection member. It is contemplated that any one or more connection members 14 coupling adjoined functional bodies 12 can include ways for selectively actuating the at least one connection member 14 to allow for the selective displacement of the at least one functional body 12 relative to another functional body 12 and, conversely, it is contemplated that any one or more connection members 14 coupling adjoined functional bodies 12 can include a flexible, non-actuating, material.

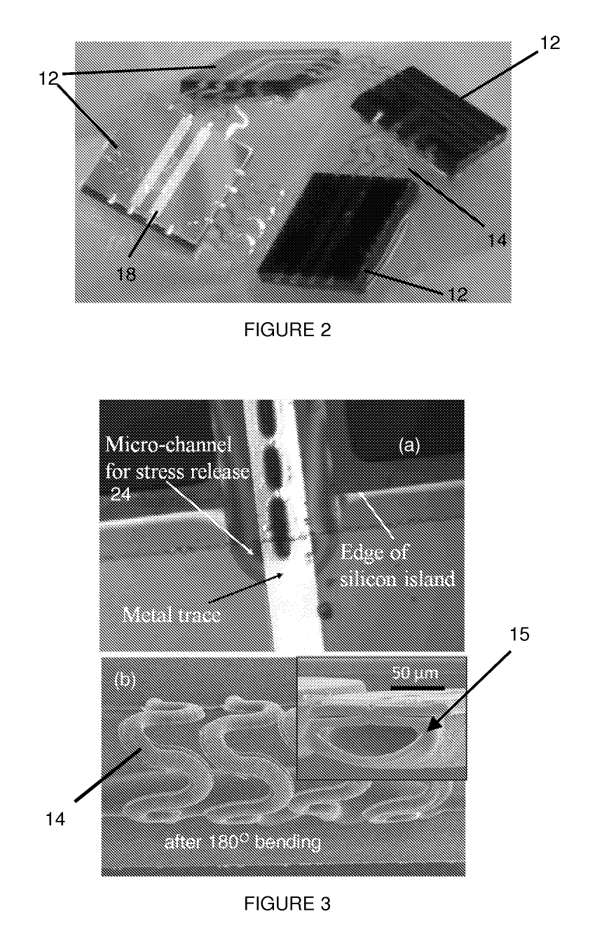

One possible arrangement for an exemplary origami enabled manufacturing system 10 is illustrated in FIG. 2. Here, four functional bodies 12 are connected in series by four connection members 14 to form a ring-like pattern.

In one aspect, and with reference to FIG. 3, the at least one connection member 14 can be formed into, for example and without limitation, a substantially “S” or serpentine-shape 22. Optionally, and without limitation, it is contemplated that the at least one connection member 14 can be substantially “C” shaped, substantially “U” shaped, substantially linear and the like. In another aspect, at least one channel 24 can be defined in a portion of the at least one connection member 14 in order to relieve a portion of the stress created during bending. Further, the at least one channel 24 defined in the at least one connection member 14 can also provide more functionality, such as pneumatic driving, and fluidic interconnection between origami pieces and with functional devices, as described more fully below.

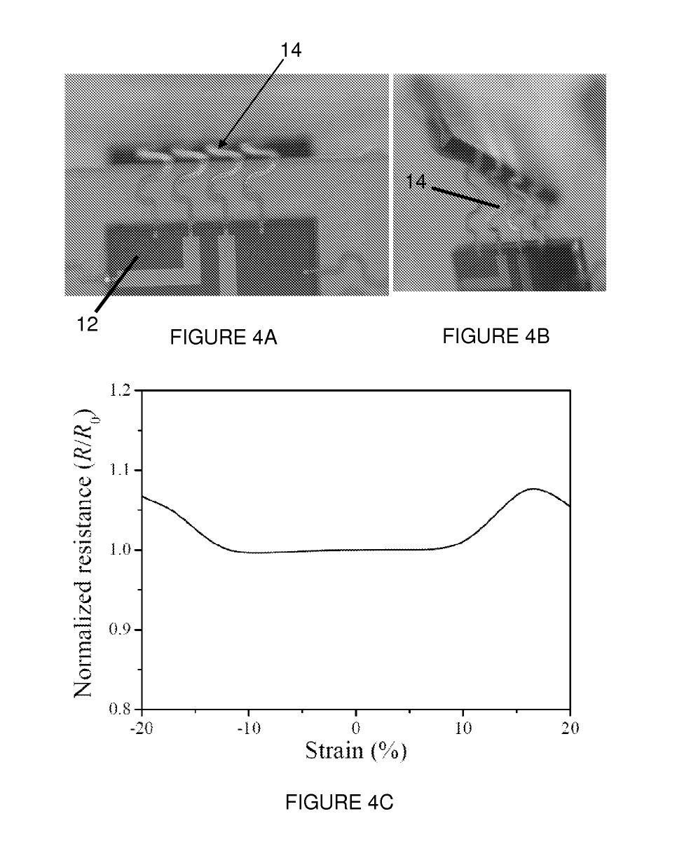

Referring now to FIG. 4A-B, the “S” or serpentine-shaped connection member 14 can survive folding (FIG. 4(A)) and twisting (FIG. 4(B)) with little change in the resistance, as illustrated in the graph in FIG. 4(C). The graph in FIG. 4(C) illustrates normalized resistance as a function of strain on the connection member 14. For example, the resistance is almost unchanged when a 2 x 2 silicon functional body 12 connected by a serpentine connection member 14 was subjected to deformations such as folding and twisting.

In one aspect, the at least one connection member 14 can be formed from a material configured to withstand the imposed bending stress formed when adjacent and adjoined functional bodies 12 are folded together to form a desired origami pattern and/or structure. In another aspect, the at least one connection member 14 can include at least one flexible layer 15 (see FIG. 3). For example, the at least one connection member 14 can be a relatively soft material, such as a polymer, gel and the like formed into a flexible layer. As an example, the polymer can be poly-para-xylylene. As another example, the polymer can be an electrically conductive polymer. In another aspect, the at least one connection member 14 can further include at least one metal material, such as, for example, and without limitation, a metal trace, e.g., Au, Cr, Cu, Ag, Al, and the like.

In another example, the at least one connection member 14 can be formed from a plurality of layers, such as a first layer forming a top or bottom of the at least one connection member 14, or double layers on both the top and bottom of the at least one connection member 14, and/or multiple layers as necessary depending on the requirements of a particular application, like that illustrated in FIG. 3. In one aspect, the flexible layer of the at least one connection member 14 can be bonded to the functional body 12 with possible reinforced folding structures. Alternatively, a fabrication process can use soft materials (such as polymer and/or gel), or a combination of soft and hard materials to produce an enhanced folding structure only at the connection between functional bodies 12. In another aspect, the soft material can be applied as a flexible layer over a functional portion of the connection member 14 (that is, optionally, over an electrode, a fluidic channel, a mechanical hinge and the like).

After fabrication and assembly of the functional bodies 12 and the at least one connection member 14 (described below according to one aspect), the origami enabled manufacturing system 10 can be folded into the origami pattern by self-assembling and/or external forces. In one aspect, the external forces can include at least one of a thermal double layer, a shape changing polymer, a shape changing alloy, an electrochemical force, a mechanical force, an electrostatic force, a magnetic force and the like. By varying the amount and/or direction of the forces, stretchability and deformability can be realized by folding and unfolding the system along the borders between the functional bodies 12. Thus, without requiring the use of elastomeric materials, stretchability and deformability can be realized. Alternatively, the functional bodies 12 can be folded to a desired folded shape before the at least one device 18 has been bonded thereto.

The folded origami shape can be the final product, according to one aspect. If so, a package can be formed to finish the system 10 with appropriate protection and/or interfaces to couple the system to its surrounding environment. If the system will be used with repeated folding and unfolding, a suitable interface can be built to connect the system with outside environments.

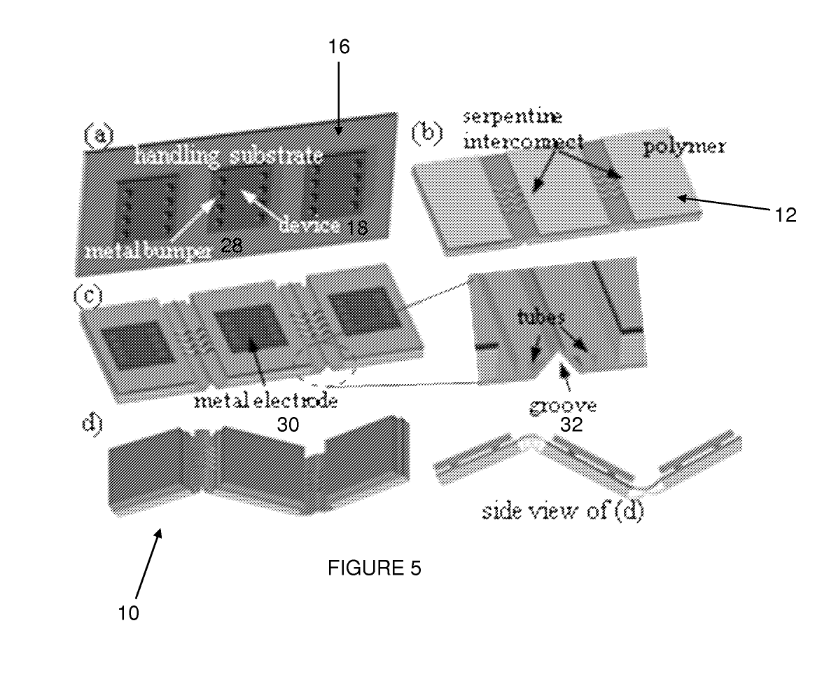

To assemble an origami enabled manufacturing system 10, in which a stretchable and deformable electronic device is formed, in one aspect, at least one electronic device 18 can be attached to a substrate 16 as illustrated in FIG. 5. The at least one device 18 can be manufactured using any industrial process. In another aspect, the at least one device 18 can be attached to the substrate 16 with, for example and without limitation, metal bonding bumpers 28. Alternatively, silicon pieces can work as an electrical and mechanical interfacing layer to introduce another functional layer on top. The functional devices 18, manufactured using industrial standard processes as an array of pieces, are attached on a handling substrate and modified with metal bonding bumpers 38. A silicon wafer with a patterned metal layer on the top surface (which functions as interconnects) and etched creases on the bottom surface is provided. The island-interconnect structures, consisting of metal electrodes encapsulated in polymer, are fabricated and the tubes around the bottom grooves are formed for potential folding. The grooves are specifically designed for origami patterns. The functional devices and the remaining structure are then brought and bonded together. Thus, the devices and polymers with origami patterns are integrated.

In one aspect, the substrate 16 of the functional body 12 can include a silicon wafer formed with a patterned metal layer 30 on a top surface of the wafer and at least one etched groove 32 on a bottom surface of the wafer. The at least one groove on the bottom surface of the wafer can be etched per a predetermined origami pattern. In another aspect, the top and bottom surface of the wafer can be at least partially covered with a polymer, such as, for example and without limitation, parylene C, to function as the connection member 14 and a guide for folding, respectively. The at least one connection member 14 can, in this example, thus consist of metal traces encapsulated in polymer.

In an embodiment, as illustrated in FIGS. 4 and 5, the functional bodies 12 may be coupled together by one or more connection members 14 that are substantially “S” or serpentine-shaped. The serpentine-shaped connection member allows the electronic device to be fully deformable, including but not limited to flexibile, stretchable, twistable, compressible, and foldable. Preferably, the serpentine-shaped connection members are formed from conductors electronically connecting the functional bodies 12.

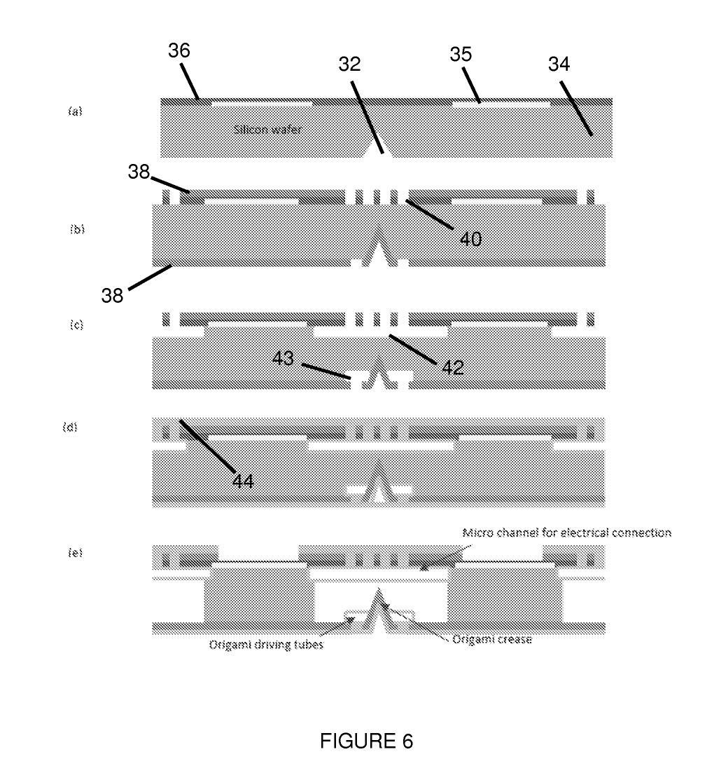

FIG. 6 illustrates a method of forming an origami enabled manufacturing system 10, wherein a silicon wafer 34 functions as the substrate. In one aspect, the silicon wafer 34 can have a thickness of, for example 300 μm. On a back surface of the wafer 34, at least one groove 32 can be defined having a groove depth of, for example 100 μm, as shown in step (a). In one aspect, the groove 32 can be patterned and etched by different approaches and chemicals, such as, for example and without limitation, Tetramethylammonium hydroxide (TMAH). On a front surface of the wafer 34, an oxide layer 35 can be patterned using photolithography and a buffered oxide etch (to about 0.5 μm in thickness), and a metal layer (e.g., an aluminum layer) 36 having a thickness of, for example, 220 nm, can be evaporated and patterned on the top surface. In step (b), a first layer 38 of polymer, such as for example and without limitation, parylene C, having a thickness of about 5 μm is deposited on top of the metal layer 36, as well as on the bottom surface of the wafer 34 using a vapor deposition method. As can be appreciated, parylene C is the generic name of poly-para-xylylene, which can be conformably deposited at room temperature with optimal mechanical and other properties. In one aspect, the parylene C layers 38 and the metal layer 36 can then be patterned by forming small holes 40 in a row along the intended center of a parylene channel. In one aspect, the holes 40 defined in the parylene C can serve as a mask for XeF₂ to etch a portion of the substrate. For example, the XeF₂ can etch a portion of the substrate to form at least one channel trench and/or tube 42 by undercutting the silicon substrate, as illustrated in step (c). In an aspect, at least one upper channel 42 can include a plurality of trenches and/or tubes defined underneath the metal layer (e.g., aluminum layer) 36. In an aspect, at least one lower channel 43 can be a plurality of trenches and/or tubes defined on a bottom surface of the substrate 16 proximate a side edge of the functional body that forms a crease in the predetermined pattern (e.g., a desired origami pattern). In an aspect, at least one upper channel 42 can be a plurality of trenches and/or tubes defined on a top surface of the substrate proximate a side edge of the functional body that forms a crease in the predetermined pattern. The plurality of upper and lower channels can be parallel to the plurality of side edges of the plurality of functional bodies. In an aspect, at least a portion of the plurality of upper channels 42 can underlie at least a portion of the at least one connection member 14, and each of the plurality of lower channels 42 can underlie each of the plurality of upper channels. In an aspect, the plurality of upper channels and the plurality of lower channels are selectively filled with air at a select air pressure. The air pressure in the upper and lower channels can be different. As illustrated in step (d), after the XeF₂ etch, a second polymer (for example, parylene C) layer 44 can be then deposited onto the substrate 16, conformably coating the trench and/or tube 42 and sealing the access holes 40 defined in the first layer 38 of parylene. In one aspect, the second and/or first parylene layer can then be patterned by oxygen plasma to shape the outline of the device and open contact pads. In another aspect, front side deep reactive ion etching (DRIE) and XeF₂ can finish the process by defining individual silicon functional bodies 12 and releasing the parylene electric connections and creases for origami, as illustrated in step (e).

Another structure used to manufacture a stretchable and deformable electronic device is the origami driving tube 42 attached to origami creases. In one aspect, these tubes can have two sets and each set can connect together. In use, air pressure or vacuum pressure can be introduced into these tubes and can provide a driving force to bend the crease up or down.

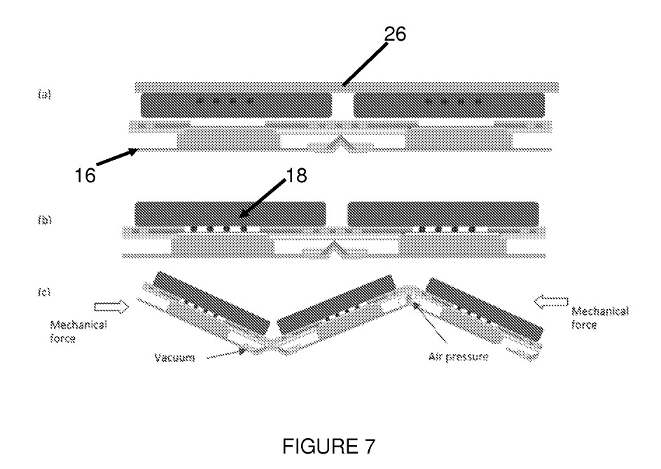

After the substrate 16 has been formed and etched as desired, the functional electronic device 18 and the substrate 16 can be aligned and brought together as illustrated in FIG. 7, steps (a) and (b). In one aspect, flip-chip bonding and/or other low temperature bonding (such as screen printing conductive epoxy bonding) can be performed to couple the device 18 to the substrate 16. Any handling surface 26 for holding the device can be removed by etching and/or other methods.

In one aspect, air pressure and/or vacuum pressure can be introduced into the tubes attached to the crease region to induce folding around the crease. For example, air pressure and/or vacuum pressure can cause a first functional body 12 to be positioned at an angle of about 20 to 30 degrees relative to a second functional body. In another aspect, a lateral mechanical compressive force can further induce folding to finish the origami folding, as illustrated in step (c). Once the origami folding is formed, air pressure and vacuum can be removed, since the folding in the polymer can retain the shapes.

This process as described herein can be scalable for mass production. The process also not only allows the integration of multiple functional devices, but also enables easy self-assembly of the origami. Specifically, asymmetries in the polymer tubes can be created in either or both of vertical and horizontal directions. By taking advantage of these asymmetries, pneumatic pressure or vacuum pressure can be applied to the channels and/or tubes to realize self-folding of the origami structure with pre-defined patterns. Furthermore, bi-stable buckling cable structures can be fabricated that allow maintainance of the folded state even after the external force is removed.

Transformative applications can be achieved when the uniqueness of origami, for instance, foldability and compactness, are integrated with functions of rigid devices. In order to develop a universal, robust, low-cost and scalable manufacturing technology by integrating origami and functional devices, foldable origami patterns can be integrated with devices in a scalable mechanism, and reliable connecting members can be positioned between functional pieces on each flat origami surface that tolerates creasing, folding, and other deformations. Once the foldable origami patterns are integrated with devices, upon folding, the functional body is not deformed, but rather is displaced due to the folding process. As shown in FIGS. 2, 5 and 7, the folding process brings the functional bodies 12 closer together, effectively making the overall product more compact.

The origami enabled manufacturing system 10 can be used in a variety of applications. For example, flexible, stretchable, foldable, and deformable electronics can be formed. The flexible electronics formed from the origami enabled manufacturing system can be formed of conventional plastic materials (used alone or in combination with elastic materials) that can be compatible with particular industry standards and high volume manufacturing technology. Further, flexible electronics formed from the origami enabled manufacturing system of the invention can easily be scaled up, are low cost, and are robust when compared to conventional systems. Flexible electronics formed from the origami enabled manufacturing system can be used, for example, in energy storage and source (e.g. battery, solar cells and supercapacitors), consumer products (e.g. foldable displays, illumination, antenna and foldable toys), wearable electronics (e.g. health monitoring system and communication system), industrial fabrication processes (chip packaging, system packaging) and the like. The origami enabled manufacturing system 10 of the invention can make these products more compact, portable and durable without sacrificing performance.

As an example, the origami enabled manufacturing system 10 can be used to improve the capacity of batteries. Conventional energy storage devices such as lithium ion (Li-ion) batteries can be considered two-dimensional (2-D) devices. The origami enabled manufacturing system 10 can be used to increase the energy per unit area such that batteries can be used for devices that have a limited area, such as for on-chip power. To maintain the same energy of the battery at a decreased footprint area, three dimensional (3-D) battery designs can be realized by implementing the disclosed methods and systems. For example, by employing the origami designs disclosed herein, an optimized conventional Li-ion battery structure can be folded to form a compact structure, which improves energy density (based on area) without using complicated electrode geometries. For example, battery arrays (e.g., devices shown in FIG. 5(A)) can be fabricated and bonded with origami patterns following the processes described herein.

Another advantage of the origami enabled manufacturing system 10 is that after manufacturing of high performance functional materials and devices on a planar surface, the planar system can become a three dimensional system which can improve the performance by increasing the actual surface area for a given planar surface area.

Another advantage of the origami enabled manufacturing system 10 is that it does not involve elastomeric materials and can be compatible with a mainstream CMOS process for high-performance devices. The systems and methods can be readily applied to other functional devices, ranging from sensors, displays, antennas, and energy storage devices. The systems and methods can be seamlessly integrated with mature microelectronics processes to fabricate functional devices that are able to survive combined stretching, compression, bending and torsion, in the planar state or the curvilinear state, or both planar and curvilinear states, with unseen functionalities. An example is origami-enabled silicon solar cells which have demonstrated that solar cells can reach up to 644% areal compactness while maintaining reasonably good performance upon cyclic folding/unfolding.

The disclosed origami enabled manufacturing systems and methods can utilize mainstream processes to fabricate high performance stretchable electronics. For example, high-performance functional devices can be fabricated on rigid surfaces without experiencing large strain during deformation, and rigid surfaces can be joined by connection members (e.g., serpentine-shaped flexible polymers) that allow for a full-degree folding and unfolding, which can enable deformability. As an example, origami enabled stretchable solar cells with metal traces embedded in serpentine-shaped flexible polymers, which function as connection members, can be fabricated to achieve unprecedented deformability. In an aspect, to bear localized strain at the creases, hollow tubes can be used with connection members as cushions to minimize the strain at folding creases.

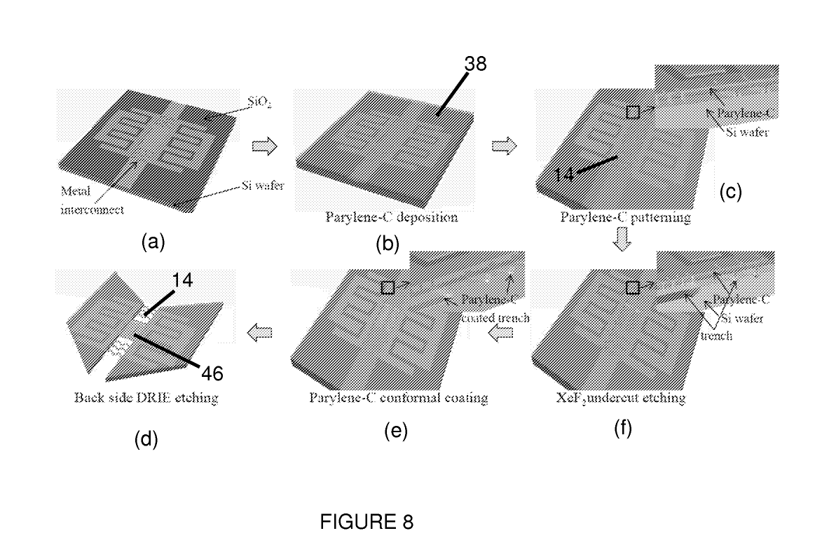

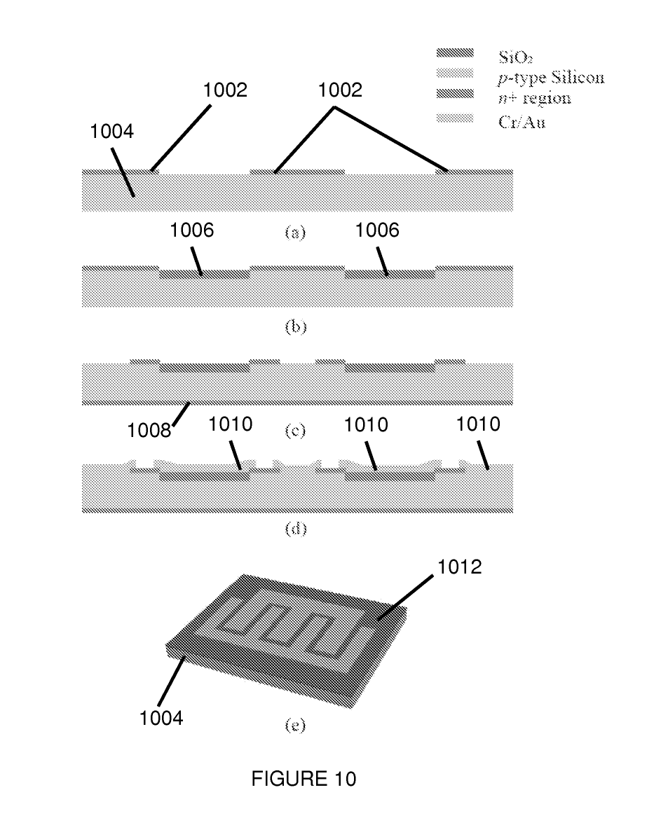

Such fabrication processes may include two processes, fabrication of an origami enabled solar cell structure (FIG. 8) and fabrication of alternative (Si) solar cells (FIG. 10).

In an aspect, the fabrication of the Si solar cells illustrated in FIG. 8 can be a standard process and compatible with mainstream CMOS processes. FIG. 8 shows two devices 18 (Si solar cells) fabricated on a Si substrate 34, and two sets of serpentine shaped connection members 14 on top of the Si wafer 34 that can be utilized to connect the two Si solar cells 18. In one aspect, the two fabricated Si solar cells 18 can be attached to a SiO₂ surface 48, as illustrated in step (a). Then, a first Parylene-C layer 38 (poly-para-xylylene) can be vapor-phase deposited using a Parylene deposition system, as shown in step (b). Parylene-C can be conformally deposited at room temperature. The first Parylene-C layer 38 can be then patterned using oxygen plasma to open small rectangular windows (e.g., 10 μm×50 μm in size and 10 μm apart between two windows) in rows along a central line of serpentine connection members 14. As shown in step (c), metal traces can be embedded in the Parylene-C connection members 14. In an aspect, back illumination can be used. In addition to patterning along connects, Parylene-C in the central area between Si solar cells 18 can also be patterned, which can form “a Parylene-C belt” 46 to enhance the mechanical integrity of the solar cells with creases. These patterned windows in Parylene-C can serve as masks for xenon difluoride (XeF₂ ) etching, a gas-phase isotropic Si etchant, as shown in step (d). The Si substrate 34 can then be undercut etched through these windows by XeF₂, forming trenches 42 underneath the connection members 14 and “Parylene-C belt”46, as shown in steps (e) and (f). These trenches can function as cushions to reduce localized stress at the connection members 14 (e.g., serpentine structures). In an aspect, deposition of a second layer of Parylene-C (15 μm in thickness) can then be conducted to conformally coat the trenches and form sealed Parylene-C microtubes underneath connection members 14 and “Parylene-C belt”46, as shown in step (e). The second layer of Parylene-C can be patterned by oxygen plasma to shape the outline of the device and open contact pads, followed by an etching method (e.g., backside deep reactive-ion etching (DRIE)) using a photoresist as mask to release the origami Si solar cells) as shown in step (f).

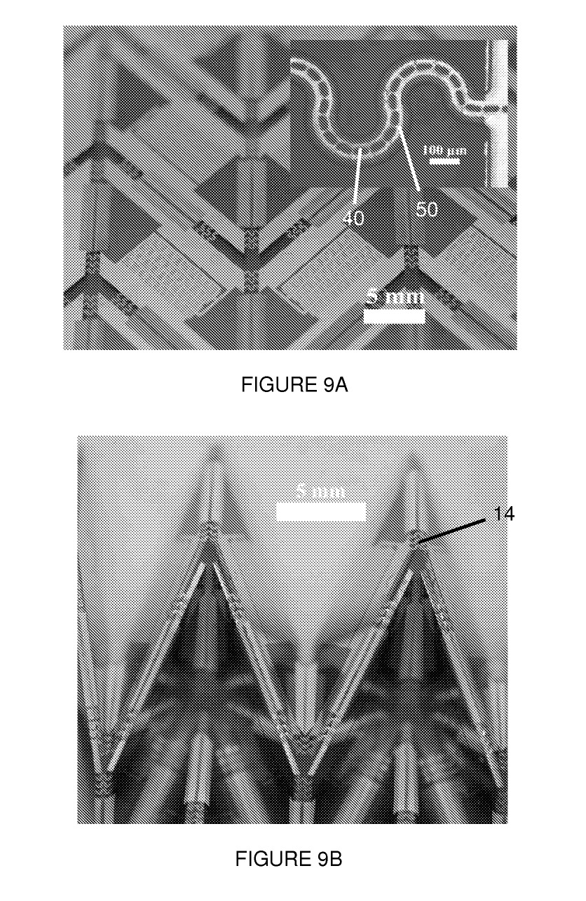

FIGS. 9(A)-(B) are photographs showing fabricated solar cells at unfolded (FIG. 9(A)) and folded (FIG. 9(B)) states. The solar cells can include twenty (20) parallelograms that are electrically linked by metal traces embedded in serpentine connection members. FIG. 9(A) shows an unfolded state with an inset of an optical micrograph of the serpentine connection member. The size of each parallelogram is 1 cm² and the slit is 0.1 cm in width. On each parallelogram, the solar cell covers 0.2 cm², which leads to 20% areal coverage, which can be significantly improved by optimized solar cell layout design. It is expected that 90% areal coverage can be reached. In the inset of FIG. 9(A), etching holes 40 for XeF₂ undercut etching are shown as dark spots, and the bright regions are gold traces 50 due to reflection of light. The Parylene-C layer that encapsulates the metal traces cannot be clearly seen because of its transparency. FIG. 9(B) shows a partially folded state and an optical micrograph as the inset confirms that the serpentine connection members can survive during folding.

FIG. 10 is a block diagram of an exemplary fabrication process for a silicon-based solar cell. The fabrication process initiates with deposition of a thin layer of silicon dioxide (SiO₂) 1002 having 0.2 μm thickness by lower pressure chemical vapor deposition (LPCVD) on a 380 μm-thick p-type single crystalline silicon (Si) wafer 1004. A patterned SiO₂ layer is formed through buffered oxide etch (BOE) using a photoresist as mask, as shown in step (a). The Si wafer 1004 is then implanted with phosphororus to form the n+ region 1006 using the patterned SiO₂ layer 1002 as the mask, as shown in step (b). The Si wafer 1004 can be annealed in a flow of dry N₂ for 30 minutes at 900° C. to form a 0.5 μm-deep p-n+ junction (not shown). Step (c) illustrates the removal of SiO₂ from potential sites of metal contacts through BOE for about 10 minutes, followed by application of an antireflection coating of SiO₂ 1008 (75 nm in thickness) on the back side of the wafer 1004 by plasma-enhanced chemical vapor deposition (PECVD). Finally, metal contacts 1010 can be applied to the wafer using electron-beam evaporation of Cr/Au 54 (10 nm/200 nm in thickness) and metal interconnects can be formed between adjacent Si solar cells, as shown in step (d). Step (e) illustrates a fabricated Si solar cell 1012 on Si wafer 1004.

The stretchability of origami based solar cells is defined by linear compactness ε_{Linear} and areal compactness ε_{Areal} using the dimensions:

$$\begin{matrix}{ɛ}_{Linear}^{x} = \frac{{L}_{x}}{{L}_{x}} for x \text{-} direction , \\ {ɛ}_{Linear}^{y} = \frac{{L}_{y}}{{l}_{y}} for y \text{-} direction , & ( 1 ) \\ {ɛ}_{Areal} = \frac{{L}_{x} {L}_{y}}{{l}_{x} {l}_{y}} = {ɛ}_{Linear}^{x} {ɛ}_{Linear}^{y} . & ( 2 )\end{matrix}$$

Lx and Ly are dimensions for the completely unfolded state in x- and y-directions (as shown in FIG. 10), respectively; and their counterparts for the completely folded states are denoted by lower case letter “l.” These measured dimensions demonstate that the origami-based solar cells have realized up to 530% linear compactness in x-direction and 644% areal compactness.

One of the keys of the invention is the employment, design and fabrication of the integrated serpentine-shaped connection member. Preferably, the connection member is an integrated 3D connection in a specially designed shape suspended in the air to connect the island structures (functional bodies). The serpentine connection member presents great flexibility and stretchablity, which provides the deformability of the whole system. The suspension in the air frees the connection member from constraints, which provides for the reliability of the whole system. Although the connection member is described as substantially “S” or serpentine-shaped, it should be understood that the description encompasess other similar shapes such as, “V”, “U”, “C” horse shoe, zigzag, spiral and the like. The serpentine shape contains self-simular patterns and rounded joints, such that it allows the connection member to be compressed or stretched or twisted, thus, imparting deformability to the final electronic device.

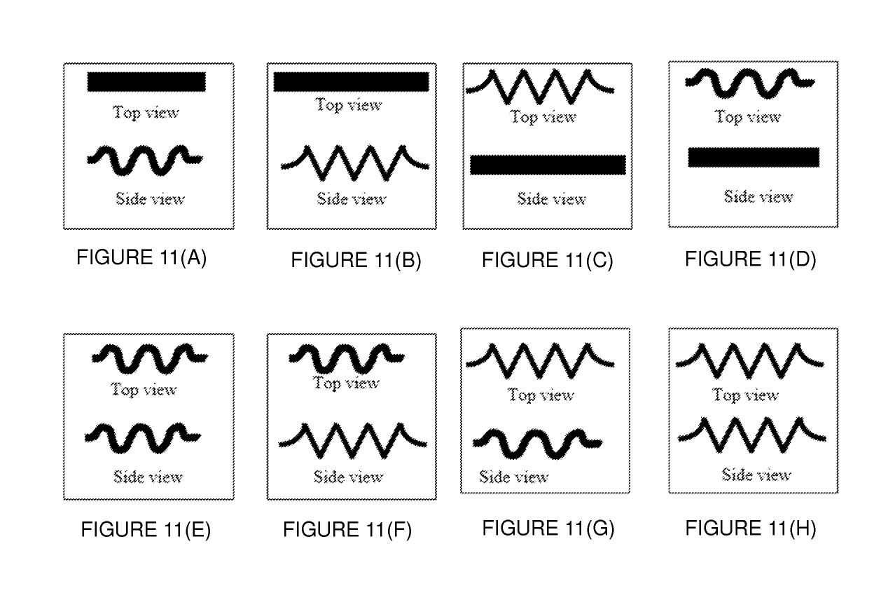

FIGS. 11(A)-(H) provide examples of several designs appropriate for the serpentine connection member. As illustrated, the serpentine shape can be in one dimension (one view) or both dimensions (top view and side view). FIGS. 11(A)-(D) depict serpentine shapes occurring in only one dimension (either the top view or the side view); FIGS. 11(E)-(H) depict serpentine shapes occurring in both directions (top view and side view). Those types of suspended ribbons can change their shape freely in any of three dimensions without damage, which provides the integrity of the whole system during deformation.

To make the serpentine interconnection, the fabrication preferably starts from a bare wafer (silicone or other materials, e.g. glass). Functional bodies or bonding bumps (for bonding other high performance wafers on top of it) can be fabricated using traditional manufacturing technology. Then, the functional bodies (islands) are formed with multiple interconnections therebetween. The fabrication process and material choice can vary depending on material choice, applications or other conditions. One way for doing this is using the method provided in Katragadda et al. (Sensors and Actuators 143:169-174, 2008) but the connection film is modified to be multiple serpentine-shaped lines.

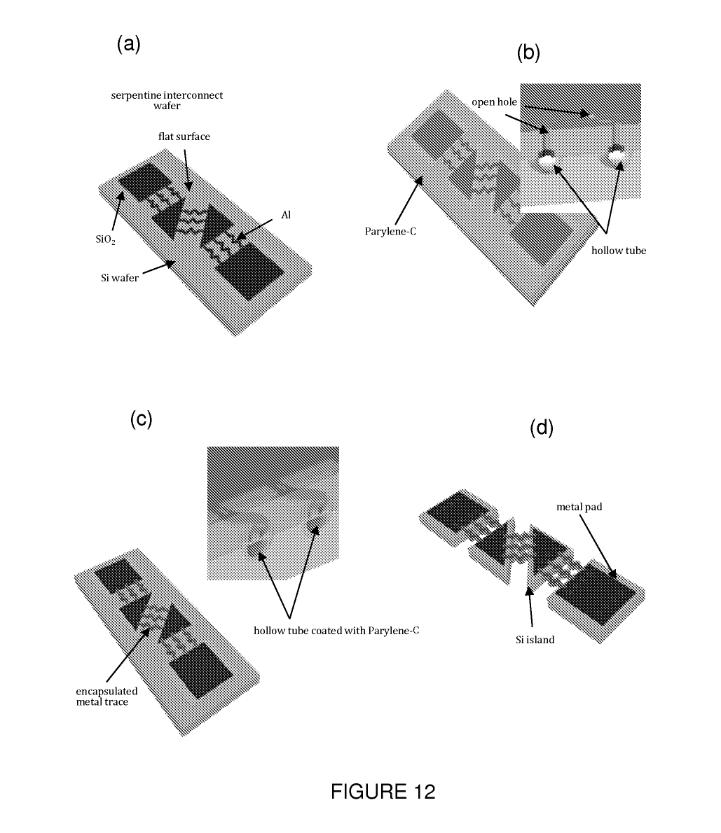

An alternate fabrication method is shown in FIG. 12. As shown in step (a), the fabrication starts with a wafer, e.g. silicon (Si), having SiO₂ patches on top functioning as passivation layers to separate the Si from the above metal pads that are connected through the serpentine-shaped metal traces (such as aluminum (Al) or copper (Cu)). The Si/SiO₂ patches serve as the flat surfaces for the rigid island. The serpentine-shaped metal is formed at the predefined creases. A thin layer of Parylene-C (poly-para-xylylene, which can be conformally deposited at room temperature) is then coated, e.g. using vapor phase deposition. Both the metal and Parylene-C layers are then etched to form open holes at the serpentine traces for the next processing step. The Si substrate underneath is subsequently undercut, e.g. by isotroppically etching using xenon difluoride (XeF₂ ) through the open holes, and thus continuous trenches in the same serpentine shapes as the metal serving as Parylene-C channel molds are formed underneath the metal trace, as shown in step (b). Another Parylene-C layer is then deposited to conformally coat the trenches, to encapsulate the serpentine-shaped metal traces, and to seal the open holes, as shown in step (c). Finally, the metal pads that act as contacts to the fabricated devices are exposed by etching away the top Parylene-C layer, and the individual Si islands are formed, e.g. by deep reactive ion etching (DRIE) from the bottom of the Si wafer, leaving the serpentine interconnects in between the islands connecting the metal pads, as shown in step (d).

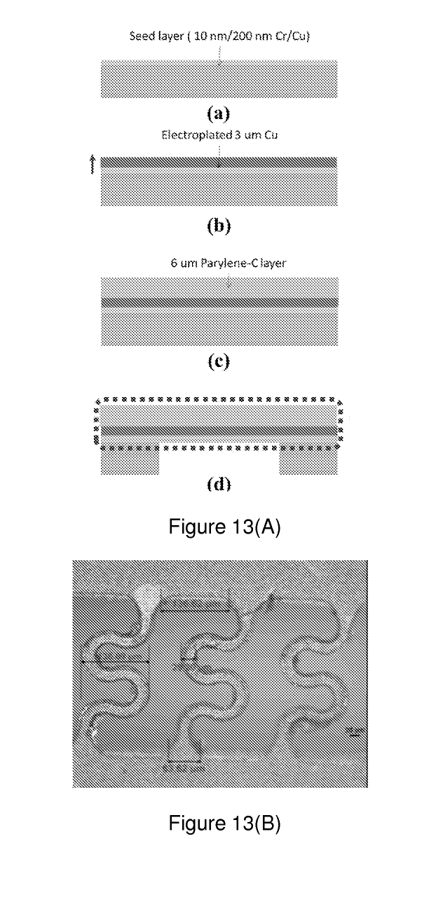

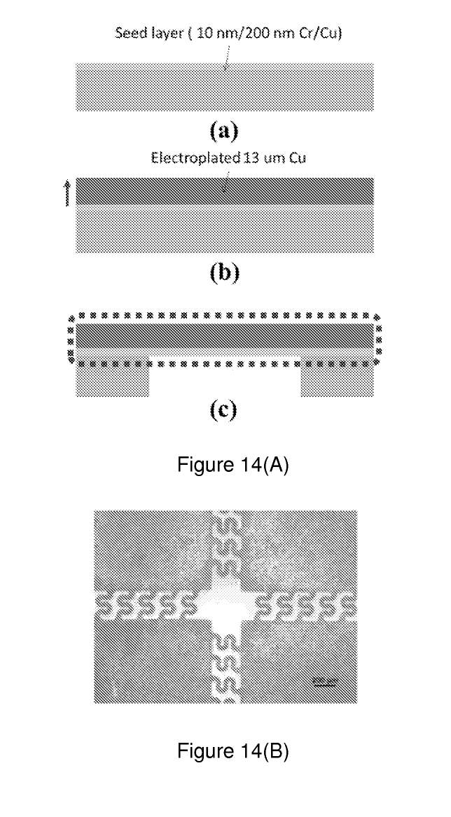

The method shown in FIG. 13 establishes a type of robust interconnection among Si islands. However, thin metal traces (about 200 nm) may provide limited power handling capability. In order to increase the thickness of the metal serpentine interconnections, electroplating may advantageously be employed, as illustrated in FIG. 14(A). In this method, chamfers in the vicinity of Si islands may also be designed to increase the strength of the interconnections. The fabrication starts from deposition of a seed layer on a Si wafer, as shown in step (a). The seed layer, for example, may contain two layers: a copper layer (50-500 nm) on top of a chromium layer (1-5-nm). Then, the seed layer is patterned with a thick layer photoresist, such as AZ4620 available from AZ Electronic Materials of Somerville, New Jersey, to make sure only serpentine interconnections and desired areas are exposed. After that, a conductive layer, such as Cu, Al, Au, Ag, Ni, and/or Pt, preferably a Cu layer (about 0.2 to about 20 μm), is electroplated and patterned to enhance the electrical conductivity of the interconnections, as shown in step (b). A polymer layer, e.g. a Parylene-C layer (about 2 to about 40 μm) is then coated and patterned on top of the conductive layer to enhance the mechanical integrity of the interconnection, as shown in step (c). Next, the individual Si islands are formed, e.g. by deep reactive ion etching (DRIE) from the bottom of the Si wafer, leaving serpentine interconnects between the islands, as shown in step (d). FIG. 13(B) shows a photograph of the serpentine interconnects formed using the electroplating method of FIG. 13(A).

Additionally, because electroplating can form very thick metal (e.g. 10-15 μm), a polymer may not be required to protect the interconnections during fabrication, thereby improving high temperature compatibility of the wafer bonding process. Based on that observation, FIG. 14(A) depicts a process similar to that shown in FIG. 13(A), except that the conductive layer is thicker (about 10-20 μm) and no protective polymer is required over the conductive layer. Instead of using conductive and polymer (Parylene-C) layers, the thickness of the conductive layer is electroplated at about 10-15 μm thickness. Here, a seed layer is first deposited on the Si wafer, as shown in step (a). The conductively layer is then electroplated on top of the seed layer at desired thickness, as shown in step (b). The individual Si islands are then formed, e.g. by deep reactive ion etching (DRIE) from the bottom of the Si wafer, leaving the serpentine interconnects between the islands, as shown in step (c). The serpentine interconnects contain no polymer overlay. FIG. 14(B) shows a top view photograph of the serpentine interconnects formed by the process of FIG. 14(A).

Further cost reduction may be accomplished by replacing silicon wafers with printed circuit board (PCB) substrates or other types of substrates comprising wires and insulators. The process starts with a substrate with pre-fabricated connections, vias, or/and functional circuits thereon. A photoresist layer is then coated on the substrate between functional circuits. A layer of polymer (about 8-15 μm), e.g., Paraylene-C, is coated onto the photoresist and pattern to expose the bond pads of the circuits. A conductive layer is deposited and patterned as serpentine interconnections between the bond pads. A second layer of polymer, e.g. Paraylene-C, is then coated, and the copper and polymer are patterned, e.g., using oxygen plasma. The substrate is cut using a dicing saw from the bottom to form island structures of the substrates. Lastly, the photo resist is removed, e.g. by soaking in acetone. This method is similar to that illustrated in FIG. 13(A), except that the PCB is cut using a dicing saw (or other cutting processes) rather than DRIE.

Overall, the top view configuration of the serpentine interconnect can vary depending on design and applications. For example, for a power inlet, a film-like wide line may be used. For high speed signal transmission, multiple serpentine bus lines may be used.

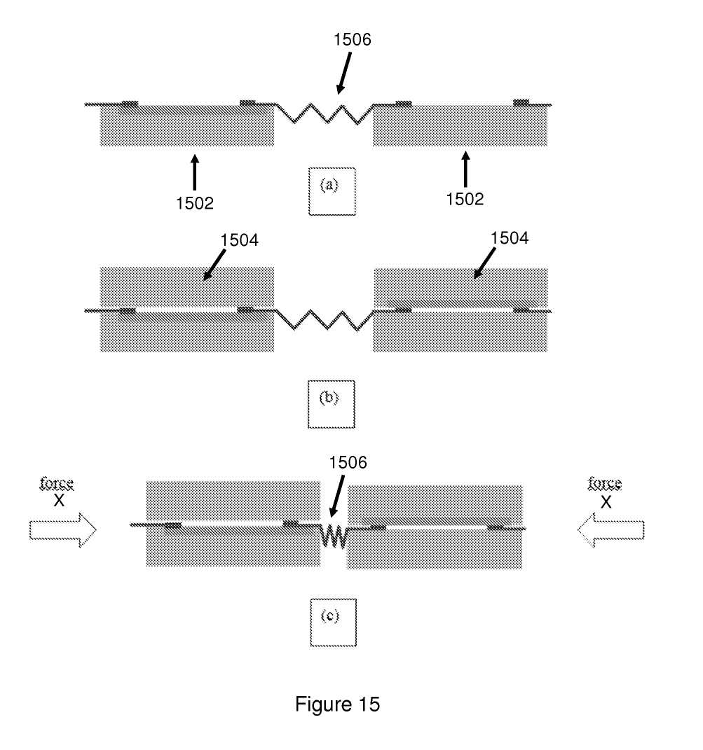

With the serpentine interconnections, pre-folded structures can be made and assembled during the fabrication process, which simplifies the folding of the interconnections. With the fabricated platform discussed above, further processing may be effected. With well designed interconnection shapes, pre-folded structures may be suitable to provide enough foldability, flexibility, stretchability and twistability to the system. As such, interconnection folding is not needed. If the pre-folded structure is not suitable, FIG. 15 illustrates a process for folding the serpentine interconnection. First, once the island platforms 1502 are made, as shown in step (a), other functional devices or/and protection dies 1504 may be bonded to the island platforms, as shown in step (b). After bonding, mechanical compressive force X is applied laterally to fold the serpentine interconnection 1506 to a compressed state, as shown in step (c). In the folded state, the electrical and mechanical integrity of the electronic device are maintained.

Finally, a packaging material is used to seal the entire structure (step not shown). Preferably, a soft elastomer or flexible material is bonded or cast on both top and bottom of the structure to seal it. The encapsulation layers may or may not be in contact with folded interconnection lines. If there is gap between encapsulation layers with interconnection lines, the interconnection lines can freely expand or shrink or move when deformation happens to the whole packaged structure. If there is no gap between encapsulation layers with interconnection lines, the interconnection lines will be protected by elastomer or plastic materials when deformation happens to the whole packaged structure. The package materials can be elastomer, such as polydimethylsiloxane (PDMS) or silicone (e.g. Ecoflex), or other polymer, such as poly(p-xylylene) polymers (e.g. Parylene). Other suitable materials include urethane, polyurethane elastomers, hydrocarbonsrubber/elastomers, and polyether block amides (PEBA), may also be used.

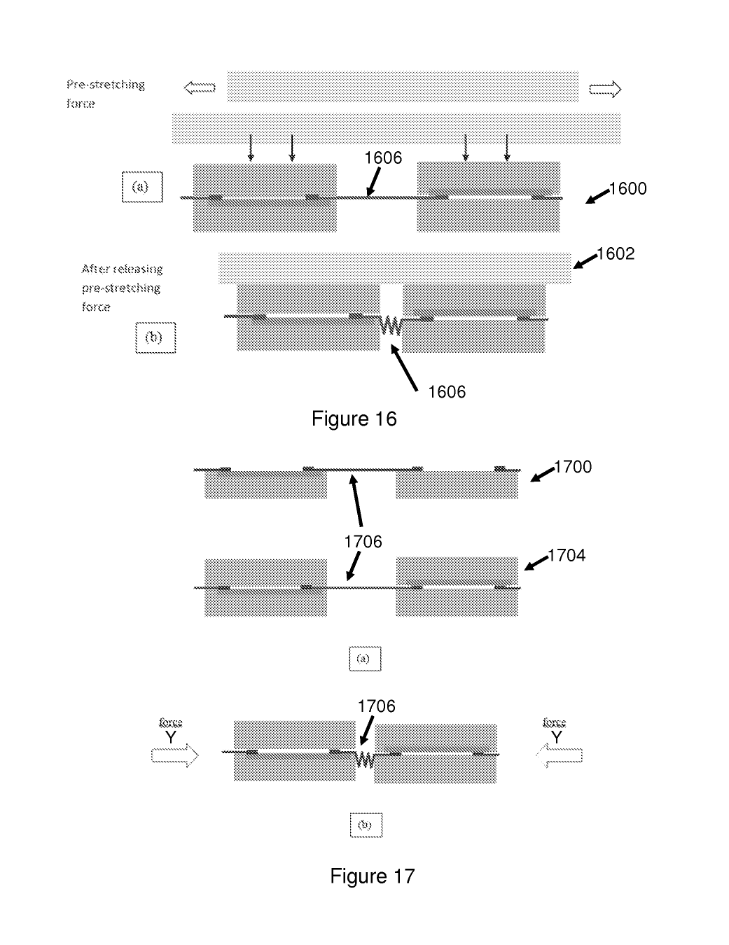

In another embodiment, the packaging may be effected as illustrated in FIG. 16. Here, the structure 1600 (including the island platforms and attached devices) and the packaging material 1602 are stretched to a desired length and then bonded together while in the stretched position, as set forth in step (a). The bonding may be on the top, bottom, or both sides of the structure. The stretching force is then released to let the serpentine interconnect 1606 spring back to its original position, as illustrated in step (b).

In a further embodiment, the folded package 1700 may be formed from a straight interconnect 1706, as illustrated in FIG. 17. Here, the interconnect is formed as a planar interconnection, and other functional devices or/and protection dies 1704 may be bonded to the island platforms 1700. After bonding, as shown in (a), mechanical compressive force Y is applied laterally to fold the planar interconnect 1706 into a folded serpentine-shaped interconnection in a compressed state, as shown in (b).

The material choice and structure design of the interconnection should be selected to optimize the interconnection's integrity and performance, including but not limited to mechanical and electrical performance. The structure design includes, but is not limited to, (1) the particular size and shape of the serpentine interconnect; (2) the optimization of an anchor structure; (3) the layer design of the line, such as single layer, double layers or triple layers with metal or alloy layer(s) in the middle, or multiple layers (for example, if insulation is needed between lines, polymers may be coated to seal the interconnection lines); and (4) additional structure to enhance the strength of the interconnection, such as an underneath hollow cable structure. Furthermore, the interconnection does not need to be soft at all locations, and foldability may be needed only at the crease regions. The interconnection may be thick or/and rigid at the segment between the creases. The materials used to form the interconnection may be hard materials, such as metals (e.g. copper, aluminum, gold, silver, etc.), nano fibers, conductive oxides (e.g. ZnO, ITO, etc.), or soft materials, such as polymers (e.g. Parylene-C, Polyimide, PDMS, etc.), or combinations thereof.

Preferred materials for the serpentine interconnect include superelastic materials, such as Nitinol (nickel and titanium compound) or shape memory alloys. Preferably, the superelastic material has up to 10˜30 times larger recoverable strain compared with other metallic materials (Cu, Au, Ag, steel, etc.).

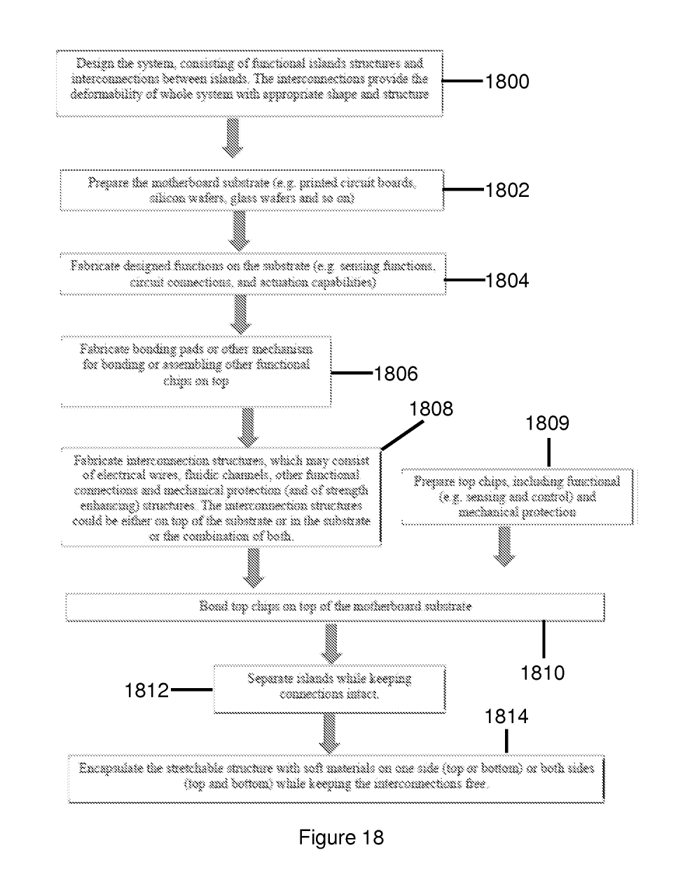

The overall design scheme for designing origami-enabled deformable electronics of the present invention is outlined in FIG. 18. Step 1800 includes the design of the system, which consists of functional islands structures and interconnections between islands. The interconnections provide the deformability of the whole system with a suitable shape and structure. Step 1802 includes preparing the motherboard structure, for example, printed circuit boards, silicon wafers, glass wafers, and the like. Step 1804 outlines the fabrication of the designed functions on the substrates, for example, sensing functions, circuit connections, and actuation capabilities. Step 1806 includes fabrication of bonding pads or other mechanisms for bonding or assembling other functional chips to the substrate. Step 1808 includes fabrication of interconnection structures, which may consist of electrical wires, fluidic channels, other functional connections and mechanical protection (and of strength enchancing) structures. The interconnection structures could be either on top of the substrate or in the substrate or a combination of both. Step 1810 includes bonding the top chips on the top of the motherboard substrate. The islands are separated while keeping the connections intact, in step Step 1812. In Step 1814, the stretchable structure is encapsulated with soft materials on one side (top or bottom), or on both sides, while keeping the interconnections free. Simultaneously with Steps 1800 through 1808, Step 1809 includes preparing top chips, including functional (e.g., sensing and control) and mechanical protection.

In an aspect, the origami enabled manufacturing systems and methods can be implemented on a computer as an automated manufacturing process. Similarly, the methods and systems disclosed can utilize one or more computers to perform one or more functions in one or more locations.

The present methods and systems can be operational with numerous other general purpose or special purpose computing system environments or configurations. Examples of well known computing systems, environments, and/or configurations that can be suitable for use with the systems and methods include, but are not limited to, personal computers, server computers, laptop devices, and multiprocessor systems. Additional examples include set top boxes, programmable consumer electronics, network PCs, minicomputers, mainframe computers, distributed computing environments that include any of the above systems or devices, and the like.

The processing of the disclosed methods and systems can be performed by software components. The disclosed systems and methods can be described in the general context of computer-executable instructions, such as program modules, being executed by one or more computers or other devices. Generally, program modules include computer code, routines, programs, objects, components, data structures, etc. that perform particular tasks or implement particular abstract data types. The disclosed methods can also be practiced in grid-based and distributed computing environments where tasks are performed by remote processing devices that are linked through a communications network. In a distributed computing environment, program modules can be located in both local and remote computer storage media including memory storage devices.

Further, one skilled in the art will appreciate that the systems and methods disclosed herein can be implemented via a general-purpose computing device in the form of a computer. The components of the computer can include, but are not limited to, one or more processors, a system memory, and a system bus that couples various system components including the processor to the system memory.

The methods and systems described above require no particular component or function. Thus, any described component or function—despite its advantages—is optional. Also, some or all of the described components and functions described above can be used in connection with any number of other suitable components and functions.

Without further description, it is believed that one of ordinary skill in the art can, using the preceding description and the following illustrative example, make and utilize the present invention and practice the claimed methods. The following example is given to illustrate the present invention. It should be understood that the invention is not to be limited to the specific conditions or details described in this example.

### EXAMPLE

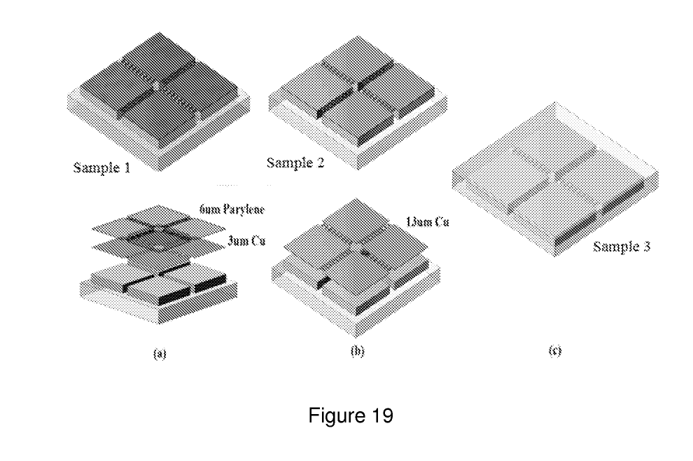

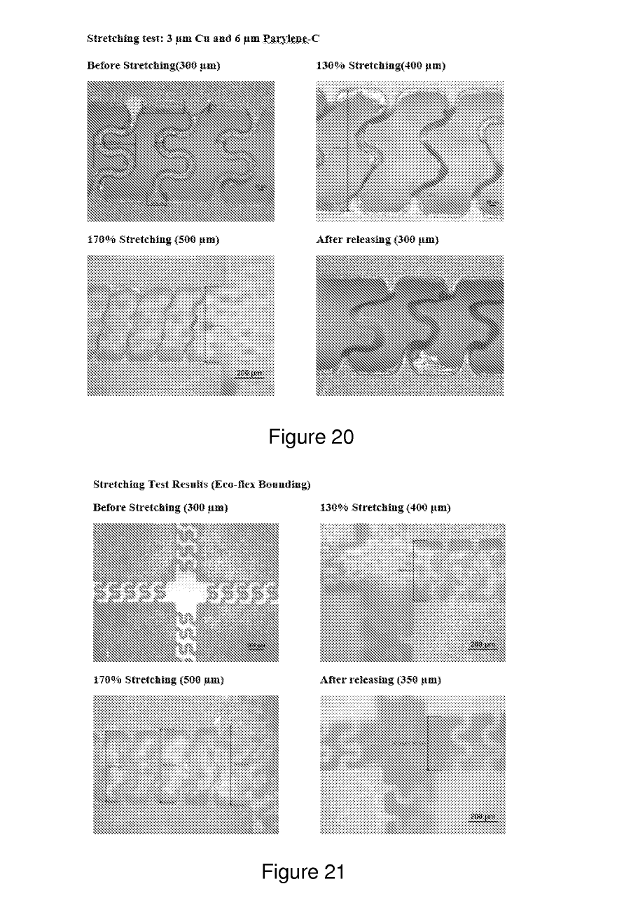

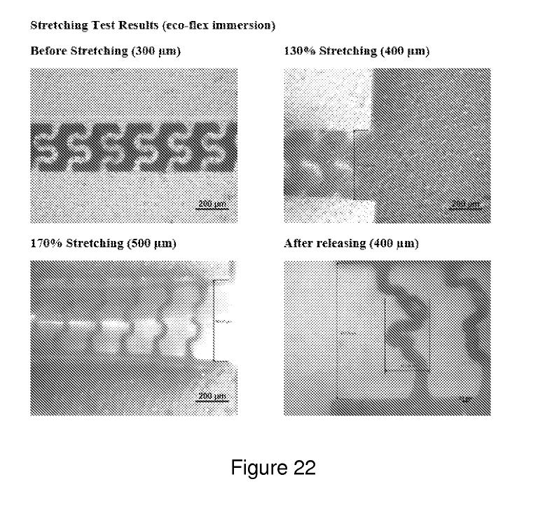

Three samples have been prepared in terms of different interconnection structures and packaging methods, shown in FIG. 19. Sample 1 was made using the method depicted in FIG. 14(A) with a 3 μm layer of copper and a 6μm layer of Parylene-C, and packaged with bounded Ecoflex. Sample 2 was made using the method depicted in FIG. 15(A) with 13 μm copper and no Parylene-C, and packaged with bounded Ecoflex. Sample 3 was made using the method depicted in FIG. 15(A) with 13 μm copper and no Parylene-C, and packaged by pouring Ecoflex to immerse the islands. FIGS. 20-22 show photographs of stretching and subsequent releasing of the stretch for Samples 1-3, respectively. Specifically, FIG. 20 is a photograph of Sample 1 as follows: (a) before stretching; (b) while stretched to 130%; (c) while stretched to 170%; and (d) after releasing the stretching. FIG. 21 is a photograph of Sample 2 as follows: (a) before stretching; (b) while stretched to 130 %; (c) while stretched to 170%; and (d) after releasing the stretching. Lastly, FIG. 22 is a photograph of Sample 3 as follows: (a) before stretching; (b) while stretched to 130%; (c) while stretched to 170%; and (d) after releasing the stretching. The following Table 1 summarizes the results:

TABLE 1
Summary for the test

| | |
|---|---|
| Sample 1 | Benefits |

| | |
|---|---|
| (3 um Cu and 6 um | Easy to pattern small feature with 3 um Cu |
| Parylene-C) | Prevent Cu oxidation |

Disadvantages

High resistivity
Poor stretchability and restorability
Parylene process complexity

| | |
|---|---|
| Sample 2 | Benefits |

| | |
|---|---|
| (13 um Cu & bounding) | Easy fabrication |
| | Low resistivity |
| | High stretchbility |

Disadvantages

Pattern small feature on 13 um Cu
Poor restorability
Cu exposed in the air

| | |
|---|---|
| Sample 3 | Benefits |

| | |
|---|---|
| (13 um Cu & immersion) | Easy fabrication |
| | Low resistivity |
| | High Stretchbility and restorability |
| | Prevent Cu oxidation |

Disadvantages

Pattern small feature on 13 um Cu
Wiring out

Although several embodiments of the invention have been disclosed in the foregoing specification, it is understood by those skilled in the art that many modifications and other embodiments of the invention will come to mind to which the invention pertains, having the benefit of the teaching presented in the foregoing description and associated drawings. It is thus understood that the invention is not limited to the specific embodiments disclosed hereinabove, and that many modifications and other embodiments are intended to be included within the scope of the appended claims. Moreover, although specific terms are employed herein, as well as in the claims which follow, they are used only in a generic and descriptive sense, and not for the purposes of limiting the described invention, nor the claims which follow.

1. An electronic device comprising:
a first functional body;
a second functional body; and
at least one connection member connecting the first functional body to the second functional body,
wherein the connection member is suspended in air to allow for stretching, flexing or compressing.

2. The electronic device of claim 1, wherein the first functional body and the second functional body are each formed of a multilayer structure.

3. The electronic device of claim 2, wherein the multilayer structure comprises a substrate layer.

4. The electronic device of claim 3, wherein the substrate layer is formed of silicon.

5. The electronic device of claim 3, wherein the substrate layer is foldable and/or flexible.

6. The electronic device of claim 2, wherein the multilayer structure comprises at least one functional device.

7. The electronic device of claim 6, wherein the at least one functional device is attached to a substrate layer of the first functional body and/or second functional body or is formed integrally with the substrate layer.

8. The electronic device of claim 6, wherein the at least one functional device may be an electronic device, a pneumatic device, or a hydraulic device.

9. The electronic device of claim 1, wherein the first functional body and/or second functional body each have at least one side edge that corresponds to creases in an origami pattern.

10. The electronic device of claim 1, wherein the at least one connection member is selectively movable between a fixed position and a pliable position, such that the first functional body may be movable relative to the second functional body or vice versa.

11. The electronic device of claim 10, further comprising an actuating mechanism for actuating the at least one connection member to move the first or second functional bodies.

12. The electronic device of claim 1, wherein the at least one connection member comprises at least one channel in a portion thereof to relieve stress during stretching, flexing, or compressing.

13. The electronic device of claim 1, wherein the at least one connection member is a conductor.

14. The electronic device of claim 1, wherein the at least one connection member is formed of a plurality of layers.

15. The electronic device of claim 14, wherein the at least one connection member includes at least one flexible layer.

16. The electronic device of claim 1, wherein the at least one connection member is a serpentine-shaped interconnect.

17. The electronic device of claim 1, wherein the at least one connection member is at least one of a “C” shaped, “U” shaped, or linear interconnect.

18. The electronic device of claim 1, wherein the electronic device is a battery.

19. The electronic device of claim 1, further comprising a third and fourth functional body, such that each of the first, second, third and fourth functional bodies are connected in series by four connection members to form a ring-like pattern.

20. A method of forming an electronic device, comprising the steps of:
attaching at least one electronic device to a front surface of at least one substrate to form at least one functional body; and
coupling each of the at least one functional bodies together with one or more connection members, wherein each of the one or more connection members is suspended in air to allow for stretching, flexing, or compressing.

21. The method of claim 20, wherein the connection members are substantially “S” or serpentine-shaped electrically conductive interconnects.

22-47. (canceled)
